(19) United States
(12) Patent Application Publication
(10) Pub. No.: US 2003/0059995 A1
(43) Pub. Date: Mar. 27, 2003

(54) Deep sub-micron raised source/drain CMOS structure and method of making the same

(76) Inventor: Sheng Teng Hsu, Camas, WA (US)

Correspondence Address: David C. Ripma, Patent Counsel, Sharp Laboratories of America, Inc., 5750 NW Pacific Rim Boulevard, Camas, WA, 98607, US

(21) Appl. No.: 09/963,078

(22) Filed: Sep. 24, 2001

(51) Int. Cl. H01L 21/8238

(52) U.S. Cl. 438/199

(57) ABSTRACT

A method of fabricating a raised source/drain CMOS device, includes preparing a silicon substrate; depositing a layer of gate oxide; forming a gate placeholder; forming a raised source/drain region having a facet located between the gate placeholder and the raised source/drain region; depositing a layer of oxide over the raised source/drain region and filling the facet; implanting, activating and diffusing ions in the raised source/drain region to form a source region and a drain region; replacing the gate placeholder with gate material; depositing a layer of passivation oxide; and metallizing the structure. A raised source/drain CMOS device includes a raised source/drain region having a facet located between the gate and the raised source/drain region; and a layer of oxide deposited over the raised source/drain region and filling the facet.

### FIELD OF THE INVENTION

This invention relates to deep sub-micron CMOS integrated circuits, and specifically, to a CMOS structure and method of fabrication the CMOS structure without forming a deep spike of silicon at the edge of a gate structure.

### BACKGROUND OF THE INVENTION

The state-of-the-art raised source/drain fabrication process is accomplished either by source/drain ion implantation, followed by selective epitaxial growth of silicon, or an initial selective epitaxial silicon growth process, followed by source/drain ion implantation. In either fabrication technique, gate electrode sidewall insulator passivation is required. These processes may form a deep spike of n+ silicon or p+ silicon at the edge of the sidewall insulator, which is the result of ion implantation through the facet of the epitaxial growth of silicon. The depth of the spike on n+ or p+ silicon enhances the device's short channel effect, degrading the performance of the device.

### SUMMARY OF THE INVENTION

A method of fabricating a raised source/drain CMOS device, includes preparing a silicon substrate; depositing a layer of gate oxide; forming a gate placeholder; forming a raised source/drain region having a facet located between the gate placeholder and the raised source/drain region; depositing a layer of oxide over the raised source/drain region and filling the facet; implanting, activating and diffusing ions in the raised source/drain region to form a source region and a drain region; replacing the gate placeholder with gate material; depositing a layer of passivation oxide; and metallizing the structure.

A raised source/drain CMOS device includes a silicon substrate, including a well therein, and isolating oxide to define a CMOS active area; a layer of gate oxide deposited on the substrate; a gate formed on the gate oxide; a raised source/drain region having a facet located between the gate and the raised source/drain region; a layer of oxide deposited over the raised source/drain region and filling the facet; doping impurities implanted and diffused into said raised source/drain region to form a source region and a drain region; a layer of passivation oxide; and metal connections.

It is an object of this invention to eliminated the n+ and p+ spike caused by the facet of the selective epitaxial growth of silicon.

Another object of the invention is to fabricate an integrated circuit wherein the series resistance of the transistor caused by the LDD region is minimized.

Yet another object of the invention is to provide a simple way of forming ultra-shallow source/drain junctions to transistor with very low series resistance.

This summary and objectives of the invention are provided to enable quick comprehension of the nature of the invention. A more thorough understanding of the invention may be obtained by reference to the following detailed description of the preferred embodiment of the invention in connection with the drawings.

### BRIEF DESCRIPTION OF THE DRAWINGS

FIGS. 1-5 depict successive steps in a first embodiment of the method of the invention using a gate replacement technique.

FIGS. 6-10 depict successive steps in a second embodiment of the method of the invention using a metal gate technique.

### DETAILED DESCRIPTION OF THE PREFERRED EMBODIMENT

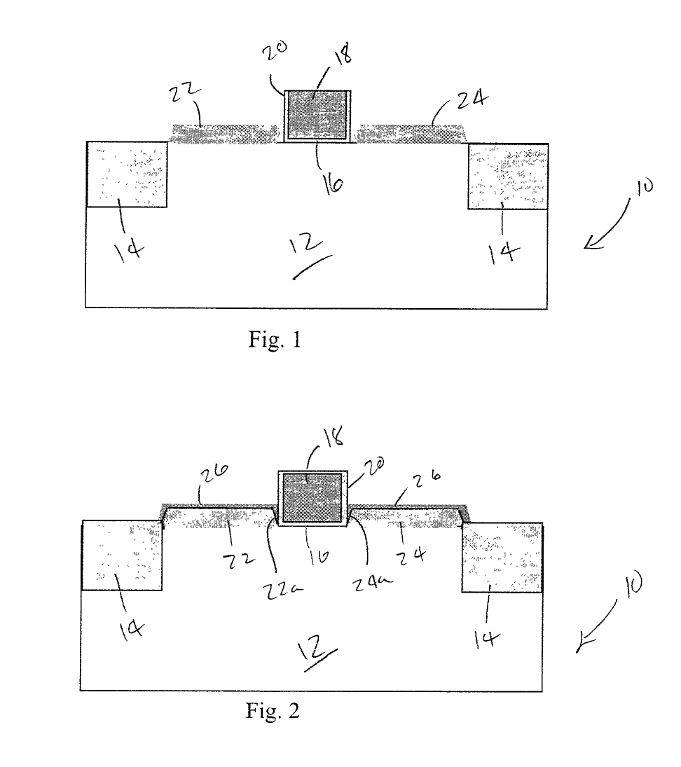

The CMOS structure and method of the invention will first be described in conjunction with a polysilicon gate replacement process as the first embodiment, and a metal gate fabrication process as the second embodiment of the method of the invention. Referring to FIG. 1, state-of-the-art processes are followed to form a CMOS active region 10, including a well 12, device isolation oxide 14, a gate oxide layer 16, and a polysilicon gate 18. Polysilicon gate 18 is also referred to herein as a gate placeholder because, while it is not removed during gate fabrication, it is converted into a material having a specific electrical property. A very thin oxide, nitride or other insulator layer 20 is passivated at the sidewall of polysilicon gate 18. The sidewall insulator is also formed by the state-of-the-art process. The sidewall insulator isolates the gate from the raised source/drain layer, but is not provided to form a drain extension region. The thickness of the sidewall insulator is between about 10 nm to 30 nm.

As shown in FIG. 1, selective growth of an epitaxial silicon layer, SiGe, or polysilicon layer 22, 24, of between about 30 nm to 80 nm thick, results in the depicted structure. The epitaxial silicon layer or polysilicon layer is referred to herein as raised source/drain material, and will eventually be doped to provide the proper electrical characteristics.

Referring now to FIG. 2, a thin layer of oxide 26 is deposited by chemical vapor deposition (CVD). This thin oxide layer is slightly thicker than the width of the facet of the epitaxial silicon or polysilicon previously grown, and is typically between about 10 nm to 30 nm thick. This CVD oxide layer fills the facet 22a, 24a, of the epitaxial silicon layer, or raised source/drain material.

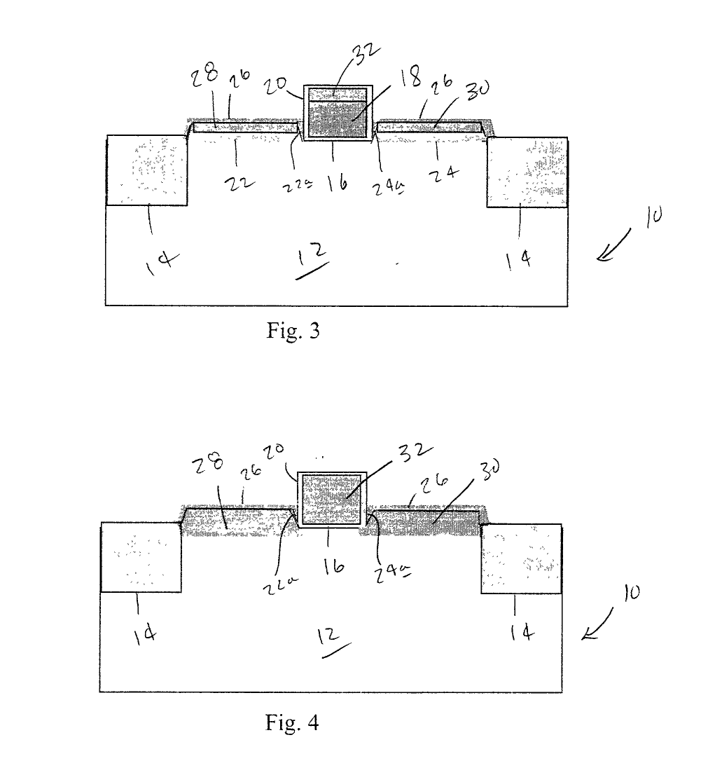

Turning to FIG. 3, the next step in the first method of the invention is source/drain ion implantation with doping impurities to form an n+ source region 28 and an n+ drain region 30, and to form an n+ region 32 in gate polysilicon 18. Thus, the polysilicon gate placeholder, rather than being removed and replaced, is converted into a n+ gate region. The depth of ion implantation should not extend into the silicon substrate. For arsenic and phosphorus ions, the energy is between about 20 keV to 90 keV and between about 10 keV to 50 keV, respectively. For boron and BF₂, the energy is between about 5 keV to 15 keV and between about 20 keV to 80 keV, respectively. The ion dose is between about 2×10¹⁵ cm⁻² to 5×10¹⁵ cm⁻². Because the facet of the epitaxial silicon is filled with CVD oxide, the projected range of the implanted ions is nearly uniform through the entire source/drain region.

FIG. 4 depicts the result following implanted ion activation and diffusion into the bulk silicon of well 12 to an optimum depth for the given channel length. This depth is between about 30 nm to 50 nm for deep sub-micron transistors.

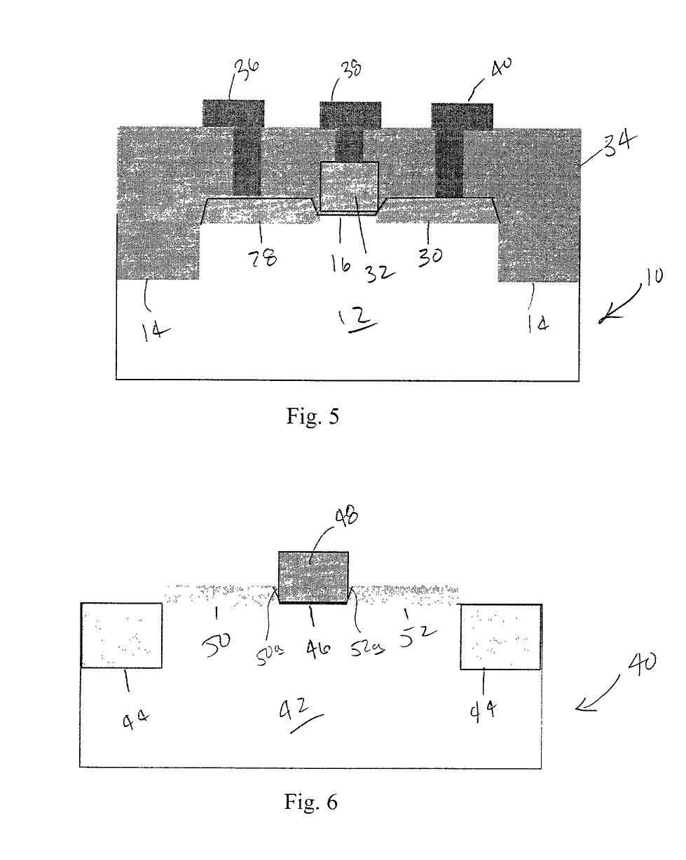

At this point, the device is ready for completion, which is accomplished by state-of the-art processes for oxide passivation 34 and metallization 36, 38, and 40, with the result being depicted in FIG. 5.

The second embodiment of the method of the invention is used for a metal gate structure, and follows steps similar to those previously described.

Referring to FIG. 6, a silicon nitride gate placeholder is used in the place of the polysilicon gate placeholder of the first embodiment, as described in connection with FIG. 1. A CMOS active region 40, including a well 42, device isolation oxide 44, a gate oxide layer 46, and a silicon nitride gate placeholder 48 are formed on the substrate. Selective growth of an epitaxial silicon layer, SiGe or polysilicon layer 50, 52, of between about 30 nm to 80 nm thick, results in the depicted structure. The epitaxial silicon layer or polysilicon layer is referred to herein as raised source/drain material, and will eventually be doped to provide the proper electrical characteristics. A gate sidewall insulator is not required in the embodiment of the method of the invention.

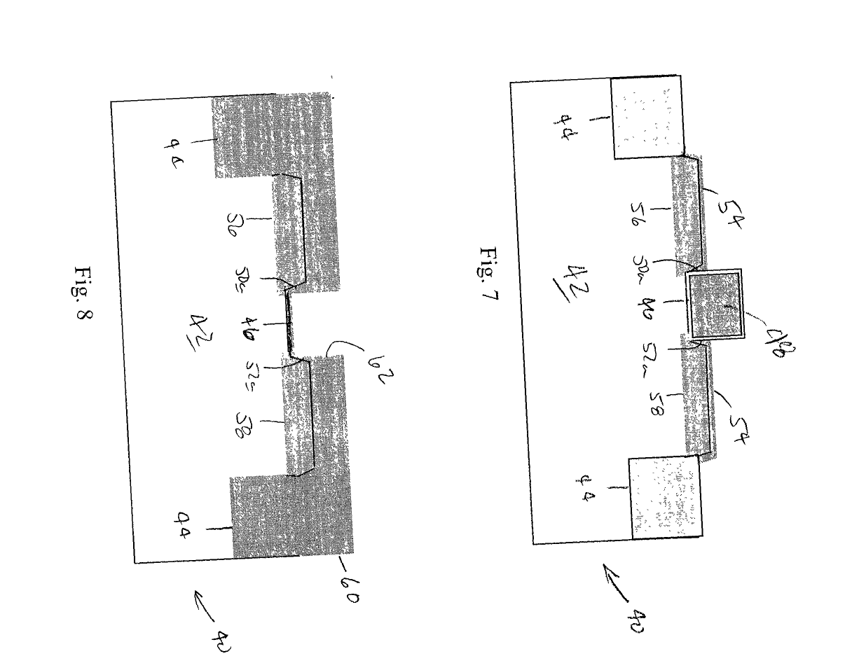

Referring now to FIG. 7, a thin layer of oxide 54 is deposited by CVD. This thin oxide layer is slightly thicker than the width of the facet of the epitaxial silicon, SiGe or polysilicon previously grown, and is typically between about 10 nm to 30 nm thick. This CVD oxide layer fills the facet of the epitaxial silicon layer, as shown at 50a, 52a, in FIG. 7. The next step is source/drain ion implantation to form a source region and a drain region. The depth of ion implantation should not extend into the silicon substrate. For arsenic and phosphorus ions, the energy is between about 20 keV to 90 keV and between about 10 keV to 50 keV, respectively. For boron and BF₂, the energy is between about 5 keV to 15 keV and between about 20 keV to 80 keV, respectively. The ion dose is between about 2×10⁵ cm⁻² to 5×10⁵ cm⁻². Because the facet of the epitaxial silicon is filled with CVD oxide, the projected range of the implanted ion is nearly uniform through the entire source region 56 and drain region 58.

Turning to FIG. 8, an oxide layer 60 is deposited and planarized by CMP, stopping at the level of the silicon nitride. The silicon nitride layer is wet etched, removing the gate placeholder, leaving a trench 62.

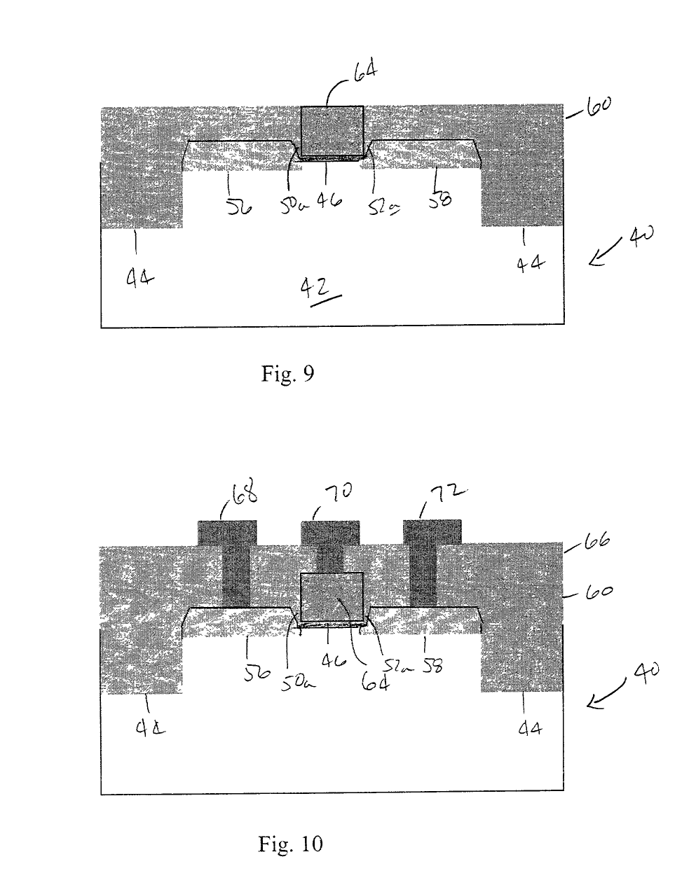

FIG. 9 depicts the result following implanted ion activation and diffusion into the bulk silicon of the substrate to an optimum depth for the given channel length. This depth is between about 30 nm to 50 nm for deep sub-micron transistors. The nitride gate placeholder may be removed after source/drain diffusion. A gate metal 64 is deposited, and smoothed by CMP, stopping at the level of oxide layer 60.

Referring to FIG. 10, a layer of oxide 66 is deposited, and the structure metallized 68, 70, 72. The metallization can be done with a Damascene process.

State-of-the-art salicidation processes are applicable to both the polysilicon gate replacement method of the invention and the metal gate method of the invention. The salicide process may be done before or after source/drain ion implantation.

Thus, a deep sub-micron raised source/drain CMOS structure and a method of making the structure has been disclosed. It will be appreciated that further variations and modifications thereof may be made within the scope of the invention as defined in the appended claims.

I claim:

1. A method of fabricating a raised source/drain CMOS device, comprising:
preparing a silicon substrate, including forming a well therein, and isolating a CMOS active area with isolating oxide;
depositing a layer of gate oxide;
forming a gate placeholder;
forming a raised source/drain region having a facet located between the gate placeholder and the raised source/drain region;
depositing a layer of oxide over the raised source/drain region and filling the facet;
implanting, activating and diffusing ions in the raised source/drain region to form a source region and a drain region;
replacing the gate placeholder with gate material;
depositing a layer of passivation oxide; and
metallizing the structure.

2. The method of claim 1 wherein said forming a gate placeholder includes forming a polysilicon gate placeholder.

3. The method of claim 2 which further includes forming a sidewall insulator about the gate placeholder.

4. The method of claim 3 wherein said forming a sidewall insulator includes forming the sidewall insulator to a thickness of between about 10 nm to 30 nm.

5. The method of claim 2 which includes implanting ions in the polysilicon gate placeholder to form an n+ gate region.

6. The method of claim 1 wherein said forming a gate placeholder includes forming a silicon nitride gate placeholder.

7. The method of claim 6 which includes removing the silicon nitride gate placeholder by etching and depositing a metal gate in place of the silicon nitride gate placeholder.

8. The method of claim 1 wherein said forming a raised source/drain region includes forming a raised source/drain region having a thickness of between about 30 nm to 80 nm.

9. The method of claim 8 wherein said forming a raised source/drain region includes selectively growing a layer of material taken from the group of material consisting of epitaxial silicon, SiGe and polysilicon.

10. The method of claim 1 wherein said depositing a layer of oxide over the raised source/drain region and filling the facet includes depositing a layer of oxide to a thickness of between about 10 nm to 30 nm.

11. The method of claim 1 wherein said implanting includes implanting ions at a dose of between about 2×10¹⁵ cm⁻⁻² to 5×10¹⁵ cm⁻², wherein the ions are taken from the group of ions consisting of arsenic ions, implanted at an energy level of 20 keV to 90 keV; phosphorus ions, implanted at an energy level of between about 10 keV to 50 keV; boron ions, implanted at an energy level of between about 5 keV to 15 keV; and BF₂ ions, implanted at an energy level of between about 20 keV to 80 keV.

12. The method of claim 11 wherein said diffusing includes diffusing the implanted ions to a depth of between about 30 nm to 50 nm into the well.

13. A raised source/drain CMOS device, comprising:
a silicon substrate, including a well therein, and isolating oxide to define a CMOS active area;
a layer of gate oxide deposited on the substrate;
a gate formed on the gate oxide;
a raised source/drain region having a facet located between the gate and the raised source/drain region;
a layer of oxide deposited over the raised source/drain region and filling the facet;
doping impurities implanted and diffused into said raised source/drain region to form a source region and a drain region;
a layer of passivation oxide; and
metal connections.

14. The CMOS device of claim 13 which further includes a sidewall insulator located about the gate.

15. The CMOS device of claim 14 wherein said sidewall insulator has a thickness of between about 10 nm to 30 nm.

16. The CMOS device of claim 13 wherein said raised source/drain region has a thickness of between about 30 nm to 80 nm.

17. The CMOS device of claim 16 wherein said a raised source/drain region is formed of material taken from the group of material consisting of epitaxial silicon, SiGe and polysilicon.

18. The CMOS device of claim 13 wherein said layer of oxide deposited over the raised source/drain region and filling the facet includes a layer of oxide having a thickness of between about 10 nm to 30 nm.

19. The CMOS device of claim 13 wherein said doping impurities includes ions implanted at a dose of between about 2×10¹⁵ cm⁻² to 5×10¹⁵ cm⁻², and wherein the ions are taken from the group of ions consisting of arsenic ions, implanted at an energy level of 20 keV to 90 keV; phosphorus ions, implanted at an energy level of between about 10 keV to 50 keV; boron ions, implanted at an energy level of between about 5 keV to 15 keV; and BF₂ ions, implanted at an energy level of between about 20 keV to 80 keV.

20. The CMOS device of claim 19 wherein said doping impurities are diffused to a depth of between about 30 nm to 50 nm into the well.
